(19) United States
(12) Patent Application Publication
(10) Pub. No.: US 2020/0209311 A1
(43) Pub. Date: Jul. 2, 2020

(54) METHOD AND DEVICE FOR DETECTING FAULTS AND PROTECTION FOR POWER SWITCHING ELECTRONIC DEVICES

(71) Applicant: INSTITUT VEDECOM, Versailes (FR)

(72) Inventor: Friedbald KIEL, Fontainebleau (FR)

(21) Appl. No.: 16/619,375

(22) PCT Filed: May 31, 2018
(86) PCT No.: PCT/FR18/51256

§ 371 Date: Dec. 4, 2019

(30) Foreign Application Priority Data
Jun. 7, 2017 (FR) 1755041

(51) Int. Cl. G01R 31/327

(52) U.S. Cl. CPC G01R 31/327

(57) ABSTRACT

The method detects a fault in a power switching electronic device (OT₁) by using the thermo-acoustic effect and comprises the steps of: a) detecting an acoustic signal (SA) generated by thermo-acoustic effect in the electronic device when it is in operation; determining (FFT) a frequency spectrum of the detected acoustic signal and obtaining, from the frequency spectrum, a spectral signature (SEP) associated with the detected acoustic signal; comparing (CSG) the spectral signature (SEP) with a plurality of reference spectral signatures (Sgn); and, deciding (CSG) on the presence of at least one fault in the electronic device when at least one coincidence is identified in the comparison step c) between the spectral signature and the plurality of reference spectral signatures.

### CROSS-REFERENCE TO RELATED APPLICATIONS

This application is the US National Stage under 35 USC § 371 of International Application No. PCT/FR2018/051256 filed 31 May 2019 which claims the priority of the French patent application 1755041 filed Jun. 7, 2017 of which the content (text, drawings and claims) is incorporated herein by reference.

### BACKGROUND

In general, the invention concerns the field of electronic power. More specifically, the invention relates to a method and a device for detecting faults and protection of proper operation in electronic power switching devices such as power modules, converters and inverters.

Electronic power switching devices are used in numerous fields and play a more and more important role, for example, in railroads, electric and hybrid cars and aeronautics. With the desired energy transition toward sources of renewable energy that emit less CO₂, electronic power is targeted to become even more widespread and must overcome increasing economic and technological constraints.

The search to meet these needs, specifically in terms of power and compactness, has given rise to considerable interest in the development of power modules that function with a high-power density. These power modules are used to function over a broad temperature range, typically from −50° C. to 175° C., or at even higher temperatures, which subjects the semi-conductor and assembly components to heavy constraints.

The manufacture of power modules requires rigorous controls, notably at the end of manufacturing, in order to detect possible faults in the electronic chips and in assemblies that specifically include substrates, baseplates, metalizations, brazing, electrical interconnection wires known as “bonding wires” or other means of electrical interconnection of chips, etc.

Furthermore, when they are in use, power modules are exposed to varying operating conditions and to temperature variation cycles which may cause faults, specifically in brazed connections, or sintering of chips, and drastically decrease the life span of power modules.

Testing of electronic power switching devices during manufacturing and during their life spans is therefore necessary in order to ensure their performance and reliability.

In the thesis, “Observations of Acoustic Emission in Power Semiconductors” by Kärkkäinen Tommi, ISBN 978-952-2659-11-8, the author presents study results and observations of acoustic phenomena displayed by power semiconductor chips and suggests that such phenomena could be used for detecting chip failures. The author identifies three types of acoustic emissions, namely, an acoustic emission linked to switches in the chip, an acoustic emission at the instant of failure of the chip, and an acoustic emission after the chip is destroyed. The author associates these phenomena with electrical discharges or the piezoelectric effect. This document does not disclose any solution for the detection of faults in power switching electronic devices.

In order to detect a fault in a material, it is known to heat the material in a pulsed manner, by thermal radiation and to identify a fault using the thermal response in the form of an infrared thermographic image.

It is also known to use the thermo-acoustic effect to heat the material by means of an ultrasonic acoustic wave. The detection of a fault results from the comparison of the Fourier transforms of the infrared thermic response of the material and of a reference thermal signature of the material itself.

The prior art thermographic solutions require an infrared imaging camera and are designed for periodic tests during manufacturing or periodic inspections conducted during the life span of the devices. These solutions are not suitable for continuous detection of faults in power switching electronic devices.

There is a need for a method of fault detection and protection in electronic power switching devices which produces a more compact and economical architecture for a fault detection and protection device, as well as continuous detection of defaults.

### SUMMARY

According to a first aspect, a method for fault detection and protection for an electronic power switching device is disclosed that uses the thermo-acoustic effect and comprises the steps of:
a) detection of an acoustic signal generated by thermo-acoustic effect in the electronic power switching device when the device is in operation,
b) determination of a frequency spectrum for the detected acoustic signal and obtaining, using the frequency spectrum of a spectral signature associated with the detected acoustic signal,
c) comparison of the detected spectral signature with a plurality of reference spectral signatures, and
d) deciding on the presence of at least one fault in the electronic power switching device when at least one match is identified in the comparison step c) between the detected spectral signature and the plurality of reference spectral signatures.

According to a specific characteristic of the method, the determination step b) comprises a Fourier transform calculation of the frequency spectrum of the detected acoustic signal.

According to a second aspect, a fault detection and protection device implemented by the method briefly disclosed above is disclosed, wherein the device is intended to monitor an electronic power switching device in which it is probable that a fault may appear. The device comprises at least one acoustic sensor, an input interface comprising amplification means, typically of the log-in type, and analog-digital conversion means, and one digital signal processing unit; wherein the digital signal processing unit comprises a spectral signature calculation software module capable of calculating a spectral signature of an acoustic signal detected by the acoustic sensor, a storage memory suitable for storing a plurality of reference spectral signatures, and a comparison and fault decision software module capable of detecting the presence of at least one fault in the electronic power switching device using the at least one match identified between the spectral signature of the detected acoustic signature and the plurality of reference spectral signatures stored in the storage memory.

According to another embodiment, the device comprises several acoustic sensors and the input interface is of the type with several input paths for acoustic signals and also comprises sampling means.

According to a specific characteristic, when a fault is detected, the digital signal processing unit delivers, as output, a fault signal intended for the electronic power switching device that is being monitored.

According to another specific characteristic, when a fault is detected, the digital signal processing unit delivers, as output, a fault alert, wherein the fault alert comprises a light, sound or a display on a screen, with or without an indication of the type of fault.

According to yet another specific characteristic, the fault detection and protection device comprises at least one ultrasonic acoustic sensor.

According to another aspect, an electronic power switching assembly is disclosed comprising at least one electronic power switching device and a fault detection and protection device, as disclosed above, that is associated with it.

According to a specific characteristic of the electronic power switching assembly, when a fault is detected, the associated fault detection and protection device gives a command to shut down the operation of the electronic power switching device or to continue its operation in a down-graded mode.

According to another specific characteristic, the electronic power switching device is presented in the form of a power module, of a converter or of an inverter and comprises at least one cavity in which an acoustic sensor is housed.

### DESCRIPTION OF THE FIGURES

Other advantages and characteristics of the method and device will become clearer upon reading the detailed description below of the several specific embodiments thereof with reference to the annexed drawings, in which:

FIG. 1 is a block-diagram of a first embodiment of an electronic power switching assembly comprising a three-phase inverter and a fault detection and protection device that is equipped with a single acoustic sensor;

FIG. 2 is a block-diagram of a second embodiment of an electronic power switching assembly comprising a three-phase inverter and another fault detection and protection device that is equipped with three acoustic sensors;

FIG. 3 is a cross-section of a conventional power module comprising an integrated acoustic sensor which is adapted for the electronic power switching assembly of FIG. 2.

### DETAILED DESCRIPTION

Electronic power switching devices are built from power modules that are associated in order to form full switching bridges such as polyphase inverters, or in order to be connected in parallel in order to conduct the desired current. The power module is typically an arm of a switching bridge.

The power modules, which are built using a planar architecture for the electronic chips, or using a 3D architecture, all have a structure of stratified layers, made of insulating or conducting materials, between which the electronic chips comprising semiconductor power switches, such as MOSFET or IGBT transistors, are integrated. Power switches typically switch at frequencies between a few hertz and a few hundred kilohertz. The result of this is repetitive heat pulses which lead to the generation of thermo-acoustic waves in the stratified structures of the power modules. The heat pulses are partially converted into mechanical energy of an acoustic nature by thermo-acoustic effect. The acoustic waves propagate, are deflected or reflected in the stratified structure of the power modules and are the bearers of information regarding this structure.

The invention leverages the above phenomenon to detect faults in electronic power switching devices. The acoustic wave produced by the electronic power switching device being monitored is detected and modifications in a spectral signature deduced from its frequency spectrum are detected by comparisons to previously recorded reference spectral signatures. Using the modifications of the spectral signature of the acoustic wave, the invention provides the detection of faults at an early stage. The invention also provides detection of the type of fault, such as, for example, a detachment or de-stratification of a layer, a crack in the fastening of a chip, a vacuum in a power module, etc.

Thus, it is possible to monitor and filter, during manufacturing, electronic power switching devices by examining their acoustic responses in relation to pre-defined specifications. During its life span, the health of an electronic power switching device can be monitored, continuously or according to a pre-defined periodicity, by an electronic monitoring unit that analyzes the acoustic waves emitted by the device so as to detect the presence of a fault and to protect the device from a risk of deterioration.

Embodiments of the invention are described below in the context of the fault detection and protection in a three-phase inverter.

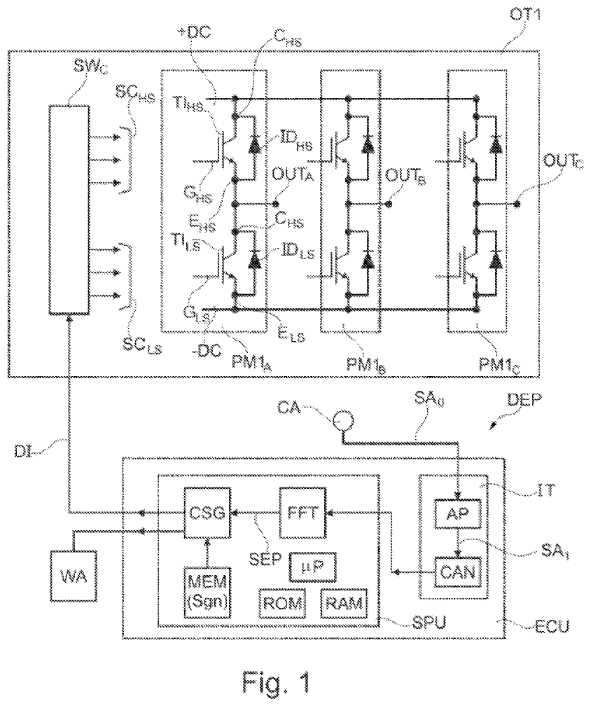

As shown in FIG. 1, a three-phase inverter OT1 comprises three power modules, PM1_{A}, PM1_{B} and PM1_{C}, and a switch command circuit SWC.

A schematic diagram of power module PM1_{A}, with IGBT type transistors, is shown in FIG. 1. The power module comprises an IGBT high-side transistor TI_{HS}, and an IGBT low-side transistor TI_{LS}. Diodes ID_{HS} and ID_{LS}, called “free wheel,” are respectively associated with transistors TI_{HS} and TI_{LS}. The diodes ID_{HS}, ID_{LS} are mounted between the collector electrodes C_{HS}, C_{LS}, respectively, and between the emitter electrode E_{HS}, E_{LS} of the transistor TI_{HS}, TI_{LS}, respectively. The collector electrode C_{HS} of the transistor TI_{HS} is connected to continuous positive voltage +DC and the emitter electrode E_{LS} of the transistor TI_{LS} is connected to continuous negative voltage −DC. The transistors TI_{HS} and TI_{LS} are switch controlled through their respective gate electrodes G_{HS} and G_{LS}. The output OUT_{A} of the PM1_{A} module corresponds to the interconnection point of the emitter electrode E_{HS} and collector electrode C_{LS} of the transistors TI_{HS} and TI_{LS} and delivers alternating current voltage.

It should also be noted that power modules PM1_{A}, PM1_{B} and PM1_{C} could also comprise other power switches, such as MOSFET transistors or GTO thyristors, etc.

The switch command circuit SWC delivers gate control signals SC_{HS}, SC_{LS}, which switch control transistors TI_{HS}, TI_{LS} of modules PM1_{A}, PM1_{B} and PM1_{C}.

As shown in FIG. 1, a fault detection device DEP is associated with a three-phase inverter OT1. An acoustic sensor CA is placed close to the inverter OT1 in order to detect an acoustic signal SA₀ emitted by the inverter. The acoustic signal SA₀ is provided to an analog input of the fault detection device DEP.

The fault detection device DEP is built around a dedicated electronic monitoring unit ECU. In another embodiment, the device DEP can be implanted in a micro-computer equipped with appropriate interface circuits.

The electronic monitoring unit ECU comprises an acoustic signal input interface IT and a digital signal processing unit SPU.

The acoustic signal input interface IT comprises an input amplifier AP and an analog-digital converter CAN. The input amplifier AP receives the acoustic signal AP as input, delivered by the acoustic sensor CA. The input amplifier AP performs a bandpass filtering of the acoustic signal SA₀ and adjusts the amplitude level of the acoustic signal for later processing. An amplified acoustic signal SA₁ is delivered as output by the amplifier AP. The amplified acoustic signal SA₁ is digitized by the analog-digital converter CAN in order to then be provided to a data input port of the digital signal processing unit SPU.

The digital signal processing unit SPU is typically built around a microprocessor μP with which is associated a read-only memory ROM and a random-access memory RAM, input/output interface means (not shown) and a storage memory MEM. A micro-program is hosted in memory in the unit SPU so as to provide the functions of signal processing by the sequential provision of series of instructions.

The functions of processing the signal executed by the unit SPU are shown in FIG. 1, in the form of the FFT and CSG blocks.

The FFT block is a software module for the calculation of the spectral signature SEP of the acoustic signal SA₁. The spectral signature SEP is deduced from the frequency spectrum of the acoustic signal SA₁ which is obtained by a Fourier transform.

The CSG block is a software module for comparison and fault decision, The SCG block compares the spectral signature SEP of the acoustic signal SA₁ with the plurality of reference spectral signals previously recorded in the storage memory MEM, so as to detect one or more possible matches between the spectral signature of the acoustic signal SA₁ and the reference spectral signals. The storage memory MEM stores a knowledge base comprising a plurality of reference spectral signatures Sgn representative of different states of functioning and different types of faults that may occur in the inverter OT1. The CSG block decides the presence of a fault and its probable type as a function of the results of the comparison. When a fault in the inverter OT1 is detected by the CSG comparison and decision module, the CSG module delivers, as output, a fault signal DI and can activate a fault alert.

The fault signal DI is transmitted to the switch command circuit SWC which can then halt the operation of the inverter OT1 by blocking at an inactive level the gate control signals SC_{HS}, SC_{IS} to the switch controlling transistors TI_{HS} TI_{LS} of the inverter OT1. The switch command circuit SWC can also command the operation of the inverter OT1 in a down-graded mode when the detected fault is less critical.

The fault alert WA can include, for example, a light or sound signal, or a display on a screen, with or without an indication of the probable type of fault.

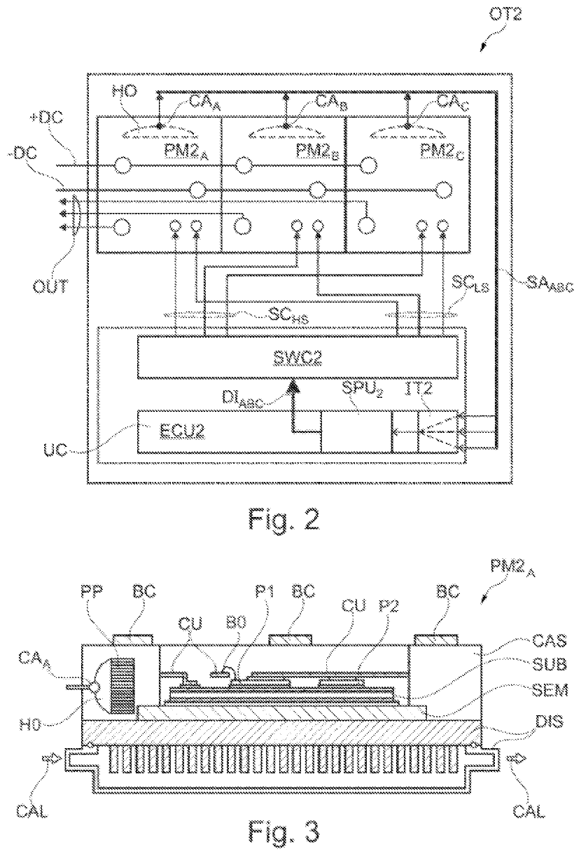

In reference to FIGS. 2 and 3, another embodiment of a three-phase inverter OT2 is disclosed, in which each of the three power modules PM2_{A}, PM2_{B} and PM2_{C} comprises an acoustic sensor CA integrated into its structure. In addition, in this embodiment, the inverter OT2 comprises an electronic control unit ECU2 dedicated to the fault detection and protection device according to the invention, which is integrated into a command unit UC of the inverter OT2.

As shown in FIG. 2, power modules PM2_{A}, PM2_{B} and PM2_{C} are arranged side by side according to a planar arrangement and comprise integrated acoustic sensors CA_{A}, CA_{B} and CA_{C}, respectively.

The command unit UC comprises a switch command circuit SWC2 and the electronic control unit ECU2. The command unit UC thus provides the switching control function of power modules PM2_{A}, PM2_{B} and PM2_{C}, by producing gate control signals SC_{HS}, SC_{L}s, and the function of fault detection and protection of the inverter OT2 in association with the acoustic sensors CA_{A}, CA_{B} and CA_{C}.

The switch command circuit SWC2 is analogous to the switch command circuit SWC of the inverter OT1 of FIG. 1 and will not be disclosed here.

The electronic control unit ECU2 is distinguished from the electronic control unit ECU of FIG. 1 in that the interface IT2 for the electronic control unit ECU2 comprises three input paths, contrary to interface IT of the electronic control unit ECU which comprises only a single path for the signal SA₀. The three acoustic signals, globally designated SA_{ABC}, which are delivered by acoustic sensors CA_{A}, CA_{B} and CA_{C}, are provided a three-path input at interface IT2, respectively. The SA_{ABC} signals are filtered and amplified, then are sampled and time-multiplexed in order to be digitized by an analog-digital converter (not shown) which is analogous to the converter CAN of interface IT (FIG. 1). A digital signal processing unit SPU2 of the electronic control unit ECU2, conducts a processing analogous to that conducted by the digital signal processing unit SPU (FIG. 1) for each of the acoustic signals SA_{ABC}. In the case of detection of a fault, the signal processing unit SPU2 is signaled to the switch command circuit SWC2 which halts the operation of the inverter OT2, or commands operation in a down-graded mode, depending on the seriousness of the detected fault. In this embodiment, due to the fact that each of the power modules is equipped with its own acoustic sensor, the detection of a fault at a power module is facilitated with respect to the form of the embodiment in FIG. 1.

It should be noted that the method is suitable for a spatial localization of the fault in the electronic power switching device. Thus, this functionality of spatial localization can be implanted using, for example, three acoustic sensors which are arranged respectively according to three different directional axes (X, Y, Z) defining a spatial identification. The spatial localization of the fault is deduced using the acoustic signals provided by the three sensors.

An example of a power module PM2_{A} comprising an acoustic sensor CA_{A}, and capable of being integrated into the inverter OT2 is shown in FIG. 3.

Power module PM2_{A} here has a conventional, planar configuration and comprises electronic chips P1, P2, which are fixed on a DBC (“Double Bond Copper”) type substrate SUB. The housing CAS of the module PM2_{A} is made by an overmolding in resin. It should be noted that, in other embodiments, the power module PM2_{A} will comprise a housing containing chips and filled with an insulating gel.

Chips P1 and P2, visible in the cross-section view of FIG. 3, are respectively a transistor TI and its associated diode DI (cf. FIG. 1) of the switching arm. Chips P1 and P2 are brazed on an upper, copper face of the substrate SUB. Copper conductors CU and bonding wires BO provide electrical connections to the inside of power module PM2_{A} and the outside connection terminals BC. An inner copper face of the substrate SUB is brazed on a metallic base plate SEM. The base plate SEM is in close thermal contact with a heat sink DIS. The heat sink DIS here is of the type which relies on circulation of a heat exchanger fluid CAL.

As shown in FIG. 3, the acoustic sensor CA_{A} is placed in the center of a cavity HO arranged in the overmolded housing CAS of power module PM2_{A}. The acoustic sensor CA_{A} is typically a piezoelectric type ultrasonic sensor for which the resonance frequency corresponds substantially to the switching frequency of the power module, for example, on the order of 40 kHz. The shape and dimensions of the cavity HO are chosen so as to improve the reception of the acoustic wave signal by the sensor CA_{A}. Optionally, a plate of porous material PP can be arranged in the cavity HO in order to filter noise from the acoustic wave.

The invention is not limited to the specific forms of embodiment that have been disclosed here as examples. The person skilled in the art, according to the applications of the invention, will be able to provide various modifications and variations which will fall within the scope of the annexed claims.

1. A method for detecting faults and protection of electronic power switching devices using the thermo-acoustic effect and comprising the steps of:
a) detecting an acoustic signal generated by thermo-acoustic effect in the electronic power switching device when the latter is in operation,
b) Determining a frequency spectrum for the detected acoustic signal and obtaining, using a frequency spectrum, a spectral signature associated with said detected acoustic signal,
c) comparing said spectral signature with a plurality of reference spectral signatures, and
d) deciding on the presence of at least one fault in said electronic power switching device when at least one match is identified in said comparison step c) between said spectral signature and said plurality of reference spectral signatures.

2. The method according to claim 1, wherein said determining step b) comprises a calculation by Fourier transform of said frequency spectrum of the detected acoustic signal.

3. A device for detecting faults and protection for the implementation of the method according to claim 1, wherein said device is intended to monitor an electronic power switching device in which a fault is likely to appear, wherein said device comprises at least one acoustic sensor, one input interface comprising amplification means and analog-digital conversion means and a digital signal processing unit; said digital signal processing unit comprising a spectral signal calculation software module capable of calculating a spectral signature of an acoustic signal detected by said acoustic sensor, a storage memory capable of storing a plurality of reference spectral signatures, and a software module for comparison and fault decision capable of detecting the presence of at least one fault in said electronic power switching device using at least one match identified between said spectral signature of said detected acoustic signal and said plurality of reference spectral signatures stored in said storage memory.

4. The device according to claim 3, wherein said device comprises a plurality of acoustic sensors and said input interface and is of the type with several acoustic signal input paths and also comprises sampling means.

5. The device according to claim 3, wherein, when a fault is detected, said digital signal processing unit delivers, as output, a fault signal for said electronic power switching device under surveillance.

6. The device according to claim 3, wherein, when a fault is detected, said digital signal processing unit delivers, as output, a fault alert comprising a light, sound or a display signal on a screen, with or without an indication of the type of fault.

7. The device according to claim 3, wherein said device comprises at least one ultrasonic acoustic sensor.

8. An electronic power switching assembly comprising at least one electronic power switching device and an associated device for detecting faults and protection, characterized in that said associated device for detecting faults and protection is a device according to claim 3.

9. The assembly according to claim 8, wherein, when a fault is detected, said associated device for detecting faults and protection commands a shutdown of said electronic power switching device or operation of the power switching device in a down-graded mode.

10. The assembly according to claim 8, characterized in that wherein said electronic power switching device is presented in the form of a power module, a converter or an inverter and comprises at least one cavity in which an acoustic sensor is housed.
